(19) United States
(12) Patent Application Publication
(10) Pub. No.: US 2024/0093364 A1
(43) Pub. Date: Mar. 21, 2024

(54) DEFECT-REDUCING COATING METHOD

(71) Applicant: MSSCORPS CO., LTD., Hsinchu (TW)

(72) Inventors: CHI-LUN LIU, Hsinchu (TW); JUNG-CHIN CHEN, Hsinchu (TW); BANG-HAO HUANG, Hsinchu (TW); YU-HAN CHEN, Hsinchu (TW); LIKO HSU, Hsinchu (TW)

(73) Assignee: MSSCORPS CO., LTD., Hsinchu (TW)

(21) Appl. No.: 17/991,826

(22) Filed: Nov. 21, 2022

(30) Foreign Application Priority Data
Sep. 19, 2022 (TW) 111135291

(51) Int. Cl. C23C 16/455; C23C 16/458

(52) U.S. Cl. CPC C23C 16/45544; C23C 16/45591; C23C 16/4581

(57) ABSTRACT

A defect-reducing coating method is disclosed, which is characterized by making the coating surface of a sample face the bottom of the coating chamber, so that the sticking particles on side walls of the coating chamber will not fall on the coating surface of the sample during the coating process, thereby a smooth coating layer can be formed on the coating surface of the sample after the coating process is finished.

This application claims the benefit of Taiwanese patent application serial No. 111135291, filed on Sep. 19, 2022, the subject matter of which is incorporated herein by reference.

### BACKGROUND OF THE INVENTION

### Field of the Invention

The invention relates in general to a coating method, and in particular to a defect-reducing coating method.

### Description of the Related Art

The atomic layer deposition (ALD) is widely used in the semiconductor process because of its advantage of isotropic growth.

A conventional atomic layer deposition (ALD) process is schematically shown in FIGS. 1A-1B. First, an atomic layer deposition (ALD) apparatus 10 comprising a chamber 20 with a top part 20A and a bottom part 20B opposite to each other as shown in FIG. 1A was provided. Next, a sample carrier 30 and a sample 40 with a coating surface 40A and a non-coating surface 40B opposite to each other were provided. The sample 40 was disposed on the surface (not labeled) of the sample carrier 30 by attaching the non-coating surface 40B thereon to make the coating surface 40A of the sample 40 face toward the top part 20A of the chamber 20. Next, the sample carrier 30 with a sample 40 disposed thereon was placed on the bottom part 20B of the chamber 20 for following atomic layer deposition (ALD) process as shown in FIG. 1A. Next, an atomic layer deposition (ALD) process as shown in FIG. 1A was applied to make a reactant gas for atomic layer deposition (ALD) flow from the top part 20A of the chamber 20 to the bottom part 20B of the chamber 20 and the coating surface 40A of the sample 40 to form an atomic layer deposition (ALD) film 50′ thereon. However, the sticky particles on the side wall of the chamber 20 fell down to the coating surface 40A of the sample 40 caused by the gravity during the atomic layer deposition (ALD) process, which resulted the obtained atomic layer deposition (ALD) film 50′ having an uneven surface as shown in FIG. 1B.

FIG. 1C is a TEM picture of an atomic layer deposition (ALD) film 50′ obtained by the conventional atomic layer deposition (ALD) process as shown in FIGS. 1A-1B at room temperature, wherein the atomic layer deposition (ALD) film 50′ is a tantalum nitride (TaN) film having a thickness of 10 nm. As the TEM picture shown in FIG. 1C, the surface of the atomic layer deposition (ALD) film 50′ is uneven because the sticky particles on the side wall of the chamber 20 fell down to the surface of the coating surface 40A of the sample caused by the gravity during the conventional atomic layer deposition (ALD) process as shown in FIGS. 1A-1B. The atomic layer deposition (ALD) film 50′ with an uneven surface will have a great adverse effect on following characteristics analysis and the accuracy of the optical defect analysis of the sample 40.

Accordingly, a defect-reducing coating method is highly expected by the industry.

### SUMMARY OF THE INVENTION

An aspect of this invention is to provide a defect-reducing coating method, comprising the steps of: providing an atomic layer deposition (ALD) apparatus comprising a chamber with a top part and a bottom part opposite to each other; providing a sample carrier comprising a stage and a plurality of supporting elements, wherein the stage comprises a top surface and a bottom surface opposite to each other, and the supporting elements are disposed on the bottom surface of the stage; providing a sample with a coating surface and a non-coating surface opposite to each other, wherein the sample is disposed and fasten on the bottom surface of the stage by the non-coating surface of the sample to make the coating surface of the sample face the bottom part of the chamber; placed the sample carrier on the bottom part of the chamber, wherein the top surface of the stage faces the top part of the chamber, and the bottom surface of the stage faces the bottom part of the chamber and spaced with each other by a distance of d (d>0); applying an atomic layer deposition (ALD) process to make a reactant gas for atomic layer deposition (ALD) flow from the top part of the chamber to the bottom part of the chamber and the coating surface of the sample to form an atomic layer deposition (ALD) film thereon; and removing the sample carrier out of the chamber and take down the sample from the sample carrier.

The above-mentioned defect-reducing coating method, wherein the sample carrier is made of a material selected from the group consisting of metal, ceramic and polymer or combinations thereof.

The above-mentioned defect-reducing coating method, wherein the sample carrier is made of stainless, copper aluminum, aluminum oxide, Teflon or aluminum oxide coated aluminum product.

The above-mentioned defect-reducing coating method, wherein a glue is coated or a double-sided tape is stick on the bottom surface of the stage and/or on the non-coating surface of the sample to make the sample be disposed and fasten on the bottom surface of the stage by the glue and/or the double-sided tape.

The above-mentioned defect-reducing coating method, wherein the glue is a hot-melt adhesive, an epoxy resin, a carbon glue or a silver glue.

The above-mentioned defect-reducing coating method, wherein the double-sided tape is a copper double-sided tape, a carbon double-sided tape or a polymer double-sided tape.

The above-mentioned defect-reducing coating method further comprises a plurality of baffles, wherein each of the baffles is equipped with each of the supporting elements, and the sample is disposed and fasten on the bottom surface of the stage by the baffles.

The above-mentioned defect-reducing coating method further comprises a plurality of baffles, wherein the baffles are disposed on the bottom surface of the stage, and the sample is disposed and fasten on the bottom surface of the stage by the baffles.

The above-mentioned defect-reducing coating method further comprises a plurality of side-clipped tenons, wherein each of the side-clipped tenons is equipped with each of the supporting elements, and the sample is disposed and fasten on the bottom surface of the stage by the side-clipped tenons.

The above-mentioned defect-reducing coating method further comprises a plurality of side-clipped tenons, wherein the side-clipped tenons are disposed on the bottom surface of the stage, and the sample is disposed and fasten on the bottom surface of the stage by the side-clipped tenons.

The above-mentioned defect-reducing coating method, wherein each of the side-clipped tenons comprises a tenon pad and a screw.

### BRIEF DESCRIPTION OF THE DRAWINGS

FIG. 1A is a schematic drawing showing a conventional atomic layer deposition (ALD) process.

FIG. 1B is a cross-sectional view of a sample with an atomic layer deposition (ALD) film formed thereon by the conventional atomic layer deposition (ALD) process as shown in FIG. 1A.

FIG. 1C is a TEM picture of an atomic layer deposition (ALD) film formed by the conventional atomic layer deposition (ALD) process as shown in FIG. 1A.

FIGS. 2A-2G are schematic drawings showing an atomic layer deposition (ALD) process according to Embodiment 1 of this present invention.

FIG. 2H is a cross-sectional view of a sample with an atomic layer deposition (ALD) film formed thereon by the atomic layer deposition (ALD) process as shown in FIGS. 2A-2G.

FIG. 2I is a TEM picture of an atomic layer deposition (ALD) film formed by the conventional atomic layer deposition (ALD) process according to Embodiment 1 of this present invention.

FIGS. 3A-3F are schematic drawings showing an atomic layer deposition (ALD) process according to Embodiment 2 of this present invention.

FIG. 3G is a cross-sectional view of a sample with an atomic layer deposition (ALD) film formed thereon by the atomic layer deposition (ALD) process as shown in FIGS. 3A-3F.

FIGS. 4A-4F are schematic drawings showing an atomic layer deposition (ALD) process according to Embodiment 3 of this present invention.

FIG. 4G is a cross-sectional view of a sample with an atomic layer deposition (ALD) film formed thereon by the atomic layer deposition (ALD) process as shown in FIGS. 4A-4F.

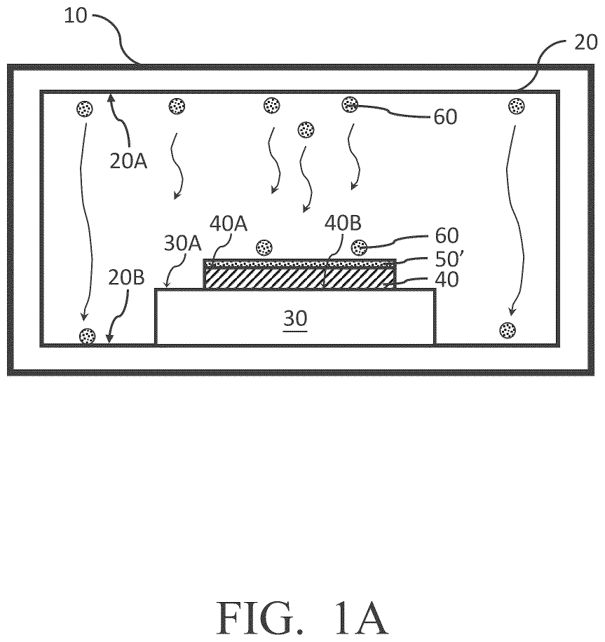

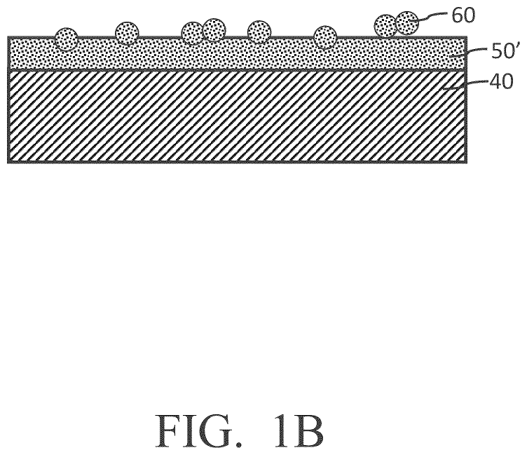

### DETAILED DESCRIPTION OF THE INVENTION

The detailed description provided below in connection with the appended drawings is intended as a description of the present examples and is not intended to represent the only forms in which the present example may be constructed or utilized. The description sets forth the functions of the example and the sequence of steps for constructing and operation the example. However, the same or equivalent functions and sequences may be accomplished by different examples.

In the following description, numerous specific details are described in detail in order to enable the reader to fully understand the following examples. However, embodiments of the present invention may be practiced in case no such specific details. In other cases, in order to simplify the drawings the structure of the apparatus known only schematically depicted in figures.

### EMBODIMENT

### Embodiment 1

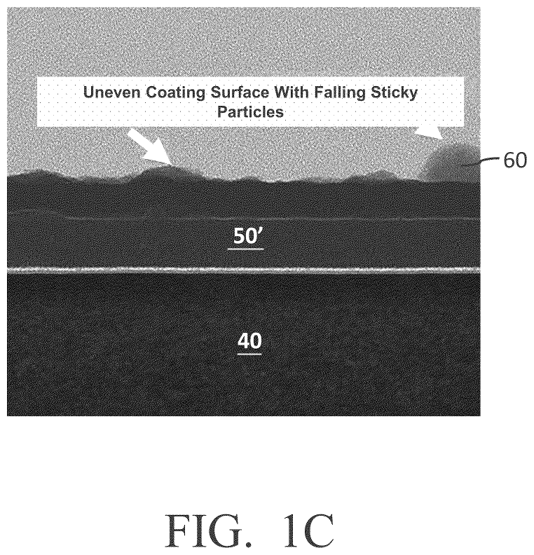

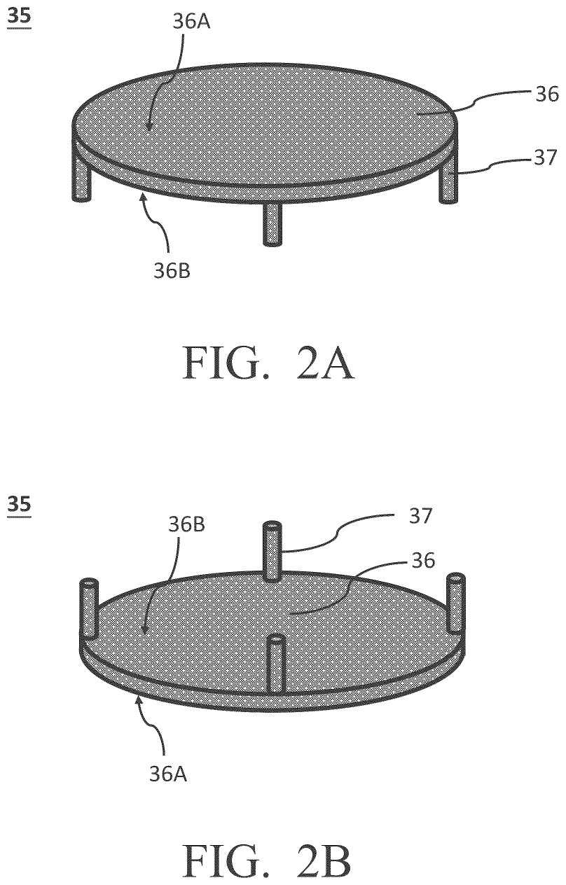

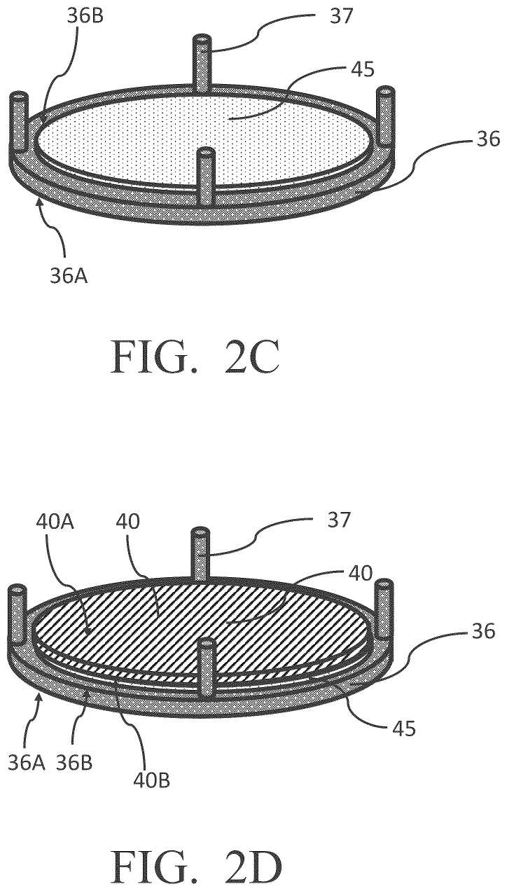

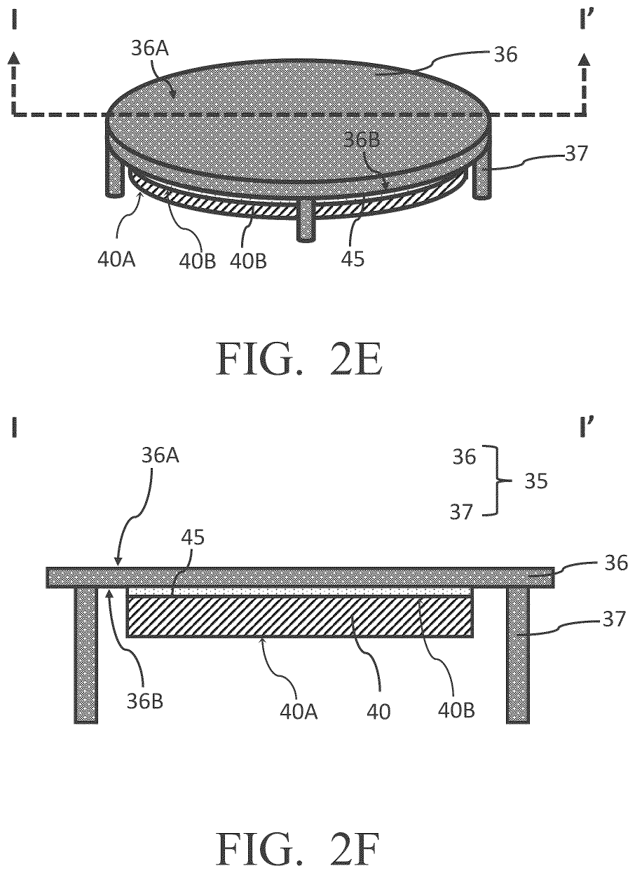

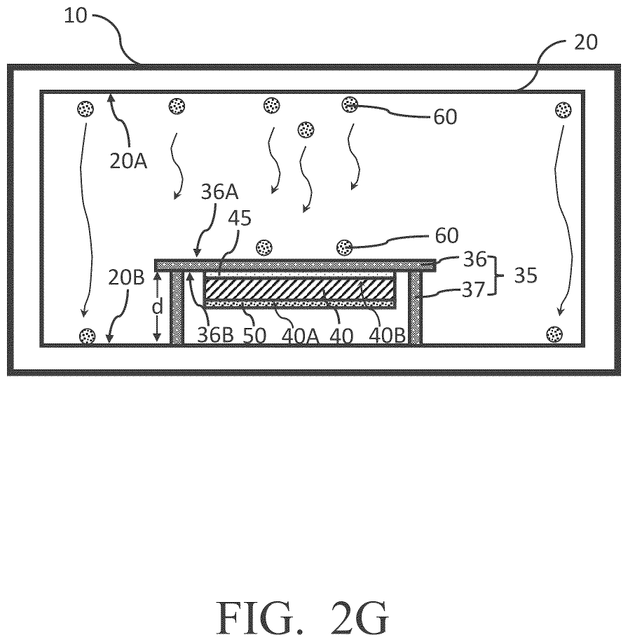

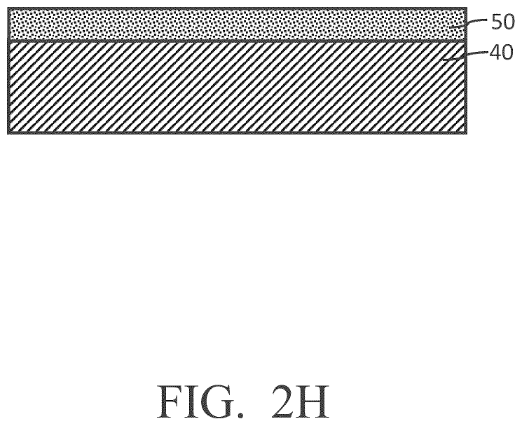

Please refer to FIGS. 2A-2I, wherein FIGS. 2A-2G are schematic drawings showing an atomic layer deposition (ALD) process according to Embodiment 1 of this present invention, FIG. 2H is a cross-sectional view of a sample with an atomic layer deposition (ALD) film formed thereon by the atomic layer deposition (ALD) process as shown in FIGS. 2A-2G, and FIG. 2I is a TEM picture of an atomic layer deposition (ALD) film formed by the conventional atomic layer deposition (ALD) process according to Embodiment 1 of this present invention.

First, an atomic layer deposition (ALD) apparatus 10 comprising a chamber 20 with a top part 20A and a bottom part 20B opposite to each other as shown in FIG. 2G was provided.

Next, a sample carrier 35 comprising a stage 36 and a plurality of supporting elements 37 as shown in FIGS. 2A-2B was provided. The stage 36 comprises a top surface 36A and a bottom surface 36B opposite to each other, and the supporting elements 37 are disposed on the bottom surface 36B of the stage 36. The sample carrier 35 can be made of a material selected from the group consisting of metal, ceramic and polymer or combinations thereof, for example but not limited to stainless, copper, aluminum, aluminum oxide, Teflon or aluminum oxide coated aluminum article.

Next, a sample 40 with a coating surface 40A and a non-coating surface 40B opposite to each other as shown in FIGS. 2C-2F was provided, and a glue 45 was coated on the bottom surface 36B of the stage 36 to make the sample 40 be disposed and fasten on the bottom surface 36B of the stage 36 by the glue 45. As shown in FIGS. 2E-2F, the coating surface 40A of the sample 40 was attached onto the bottom surface 36B of the stage 36. The glue 45 according to this Embodiment 1 can be for example but not limited to a hot-melt adhesive, an epoxy resin, a carbon glue or a silver glue. According to other Embodiments of this present invention, the glue 45 can alternatively be coated on the non-coating surface 40B of the sample 40, or the glue 45 can alternatively be coated on the bottom surface 36B of the stage 36 and the non-coating surface 40B of the sample 40.

According to another Embodiment of this present invention, a double-sided tape (not shown) can also be used to replace the above-mentioned glue 45 and be stick on the bottom surface 36B of the stage 36 and/or the non-coating surface 40B of the sample 40 to make the sample 40 be disposed and fasten on the bottom surface 36B of the stage 36 by the double-sided tape (not shown). The double-sided tape can be for example but not limited to a copper double-sided tape, a carbon double-sided tape or a polymer double-sided tape.

Next, the sample carrier 35 shown in FIGS. 2E-2F was placed on the bottom part 20B of the chamber 20 shown in FIG. 2G. As shown in FIG. 2G, the top surface 36A of the stage 36 faces the top part 20A of the chamber 20, and the bottom surface 36B of the stage 36 faces the bottom part 20B of the chamber 20 and spaced with each other by a distance of d (d>0). As shown in FIG. 2G, the coating surface 40A of the sample faces toward the bottom part 20B of the chamber 20, and the non-coating surface 40B faces toward the top part 20A of the chamber 20.

Next, an atomic layer deposition (ALD) process as shown in FIG. 2G was applied to make a reactant gas for atomic layer deposition (ALD) flow from the top part 20A of the chamber 20 to the bottom part 20B of the chamber 20 and the coating surface 40A of the sample 40 to form an atomic layer deposition (ALD) film 50 thereon.

The atomic layer deposition (ALD) film 50 according to the Embodiment 1 of this invention is a tantalum oxynitride film with a thickness for example but not limited to 10 nm deposited at a temperature for example but not limited to room temperature. Alternatively, the atomic layer deposition (ALD) film 50 can be another metal oxide film for example but not limited to a titanium oxide (TiO₂) film, an aluminum oxide (Al₂O₃) film, a hafnium oxide (HfO₂) film, a platinum oxide (PtO₂) film, an indium tin oxide (ITO) film or an indium gallium zinc oxide (IGZO) film. Alternatively, the atomic layer deposition (ALD) film 50 can also be a metal nitride film for example but not limited to an aluminum nitride (AlN) film, a molybdenum nitride (MoN) film, a titanium nitride (TiN) film or a tantalum nitride (TaN) film. Alternatively, the atomic layer deposition (ALD) film 50 can also be a metal oxynitride film.

Finally, the sample carrier 35 was removed out of the chamber 20, and then the sample 40 was taken down from the stage 36 of the sample carrier 35. Thereafter, a sample 40 with an atomic layer deposition (ALD) film 50 formed on the coating surface 40A thereof as shown in FIG. 2H was obtained.

As the TEM picture shown in FIG. 2I, the surface of the obtained atomic layer deposition (ALD) film 50 according to this Embodiment 1 formed on the coating surface 40A of the sample 40 is extremely flat because no sticky particles 60 on the side-wall (not labeled) of the chamber 20 fell down to the coating surface 40A of the sample 40 facing the bottom part 20B of the chamber 20 caused by the gravity during the atomic layer deposition (ALD) process.

### Embodiment 2

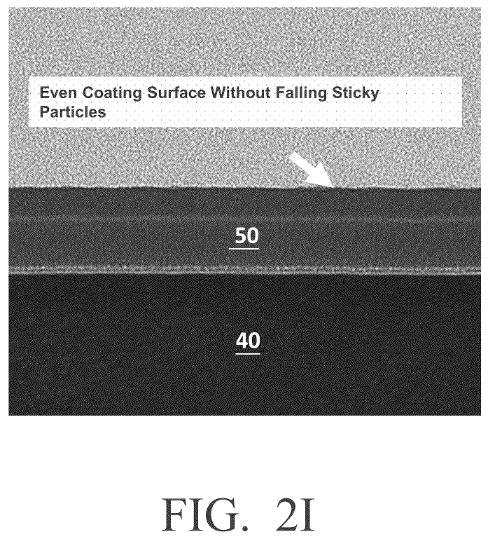

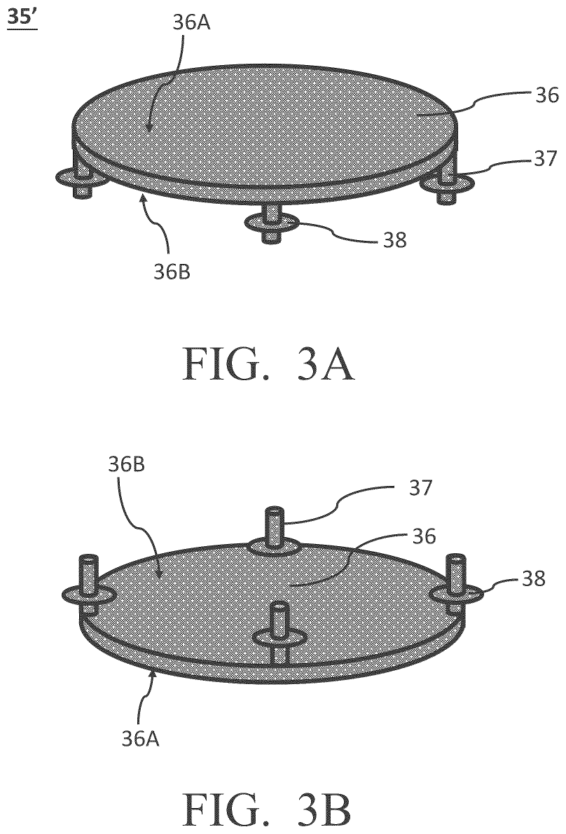

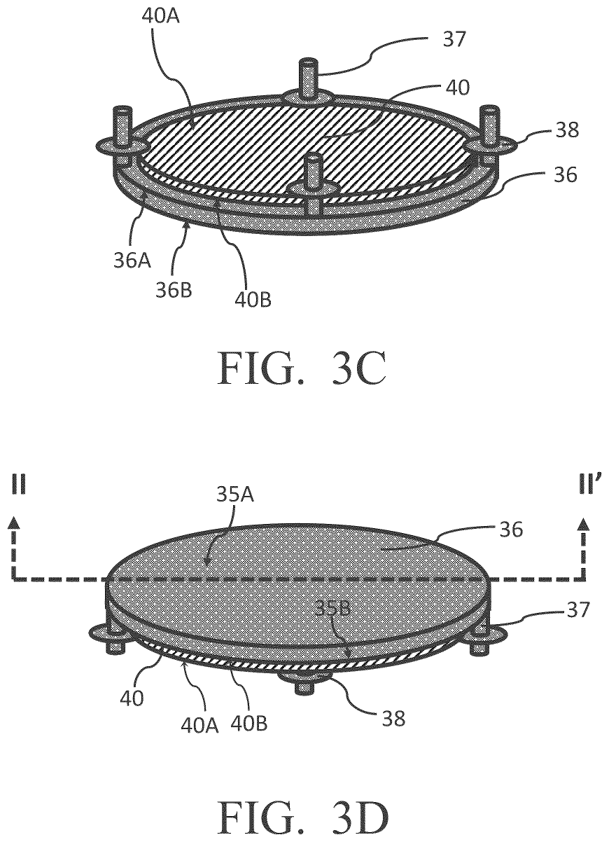

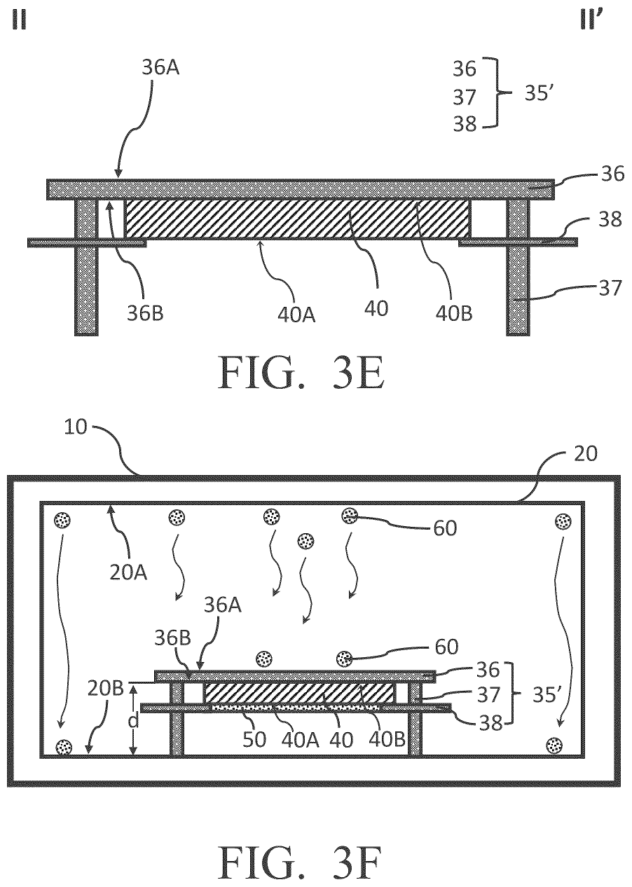

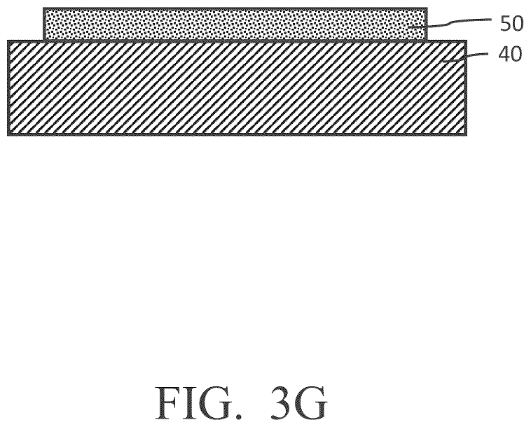

Please refer to FIG. 3A-3G, wherein 3A-3F are schematic drawings showing an atomic layer deposition (ALD) process according to Embodiment 2 of this present invention, FIG. 3G is a cross-sectional view of a sample with an atomic layer deposition (ALD) film formed thereon by the atomic layer deposition (ALD) process as shown in FIGS. 3A-3F.

First, an atomic layer deposition (ALD) apparatus 10 comprising a chamber 20 with a top part 20A and a bottom part 20B opposite to each other as shown in FIG. 3F was provided.

Next, a sample carrier 35′ comprising a stage 36, a plurality of supporting elements 37 and a plurality of baffles 38 as shown in FIGS. 3A-3B was provided. The stage 36 comprises a top surface 36A and a bottom surface 36B opposite to each other, and the supporting elements 37 are disposed on the bottom surface of the stage 36, and each of the baffles 38 is equipped with each of the supporting elements 37. The sample carrier 35′ can be made of a material selected from the group consisting of metal, ceramic and polymer or combinations thereof, for example but not limited to stainless, copper aluminum, aluminum oxide, Teflon or aluminum oxide coated aluminum product.

Next, a sample 40 with a coating surface 40A and a non-coating surface 40B opposite to each other as shown in FIGS. 3C-3E was provided, and the sample 40 was disposed and fasten on the bottom surface 36B of the stage 36 by the baffles 38. Alternatively, the baffles 38 can also be disposed on the bottom surface 36B of the stage 36 (not shown), and the sample 40 was disposed and fasten on the bottom surface of the stage by the baffles.

Next, the sample carrier 35′ shown in FIGS. 3C-3E was placed on the bottom part 20B of the chamber 20 shown in FIG. 3F. As shown in FIG. 3F, the top surface 36A of the stage 36 faces the top part 20A of the chamber 20, and the bottom surface 36B of the stage 36 faces the bottom part 20B of the chamber 20 and spaced with each other by a distance of d (d>0). As shown in FIG. 3F, the coating surface 40A of the sample faces toward the bottom part 20B of the chamber 20, and the non-coating surface 40B faces toward the top part 20A of the chamber 20.

Next, an atomic layer deposition (ALD) process as shown in FIG. 3F was applied to make a reactant gas for atomic layer deposition (ALD) flow from the top part 20A of the chamber 20 to the bottom part 20B of the chamber 20 and the coating surface 40A of the sample 40 to form an atomic layer deposition (ALD) film 50 thereon.

The atomic layer deposition (ALD) film 50 according to the Embodiment 2 of this invention is a tantalum oxynitride film with a thickness for example but not limited to 10 nm deposited at a temperature for example but not limited to room temperature. Alternatively, the atomic layer deposition (ALD) film 50 can be another metal oxide film for example but not limited to a titanium oxide (TiO₂) film, an aluminum oxide (Al₂O₃) film, a hafnium oxide (HfO₂) film, a platinum oxide (PtO₂) film, an indium tin oxide (ITO) film or an indium gallium zinc oxide (IGZO) film. Alternatively, the atomic layer deposition (ALD) film 50 can also alternatively be a metal nitride film for example but not limited to an aluminum nitride (AlN) film, a molybdenum nitride (MoN) film, a titanium nitride (TiN) film or a tantalum nitride (TaN) film. Alternatively, the atomic layer deposition (ALD) film 50 can also alternatively be a metal oxynitride film.

Finally, the sample carrier 35′ was removed out of the chamber 20, and then the sample 40 was taken down from the stage 36 of the sample carrier 35. Thereafter, a sample 40 with an atomic layer deposition (ALD) film 50 formed on the coating surface 40A thereof as shown in FIG. 3G was obtained.

The surface of the obtained atomic layer deposition (ALD) film 50 according to this Embodiment 2 formed on the coating surface 40A of the sample 40 is extremely flat because no sticky particles 60 on the side-wall (not labeled) of the chamber 20 fell down to the coating surface 40A of the sample 40 facing the bottom part 20B of the chamber 20 caused by the gravity during the atomic layer deposition (ALD) process.

### Embodiment 3

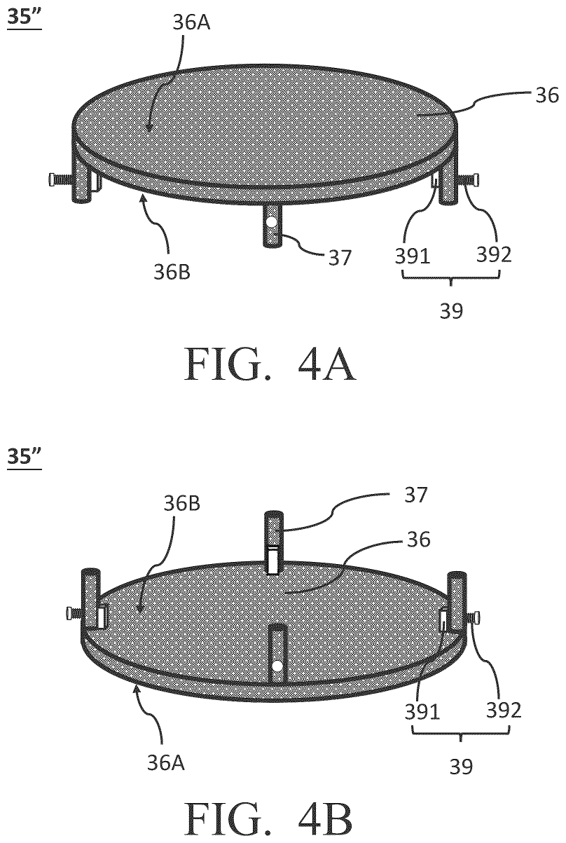

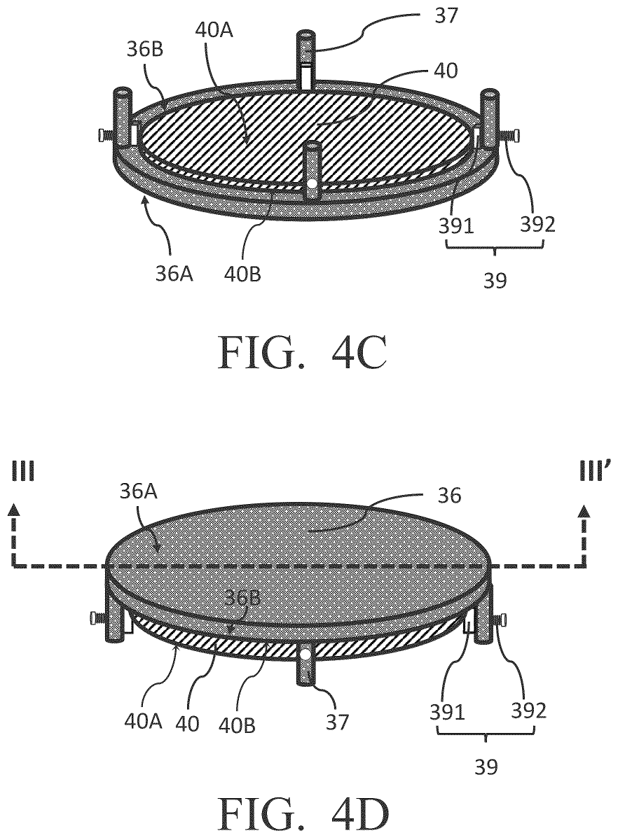

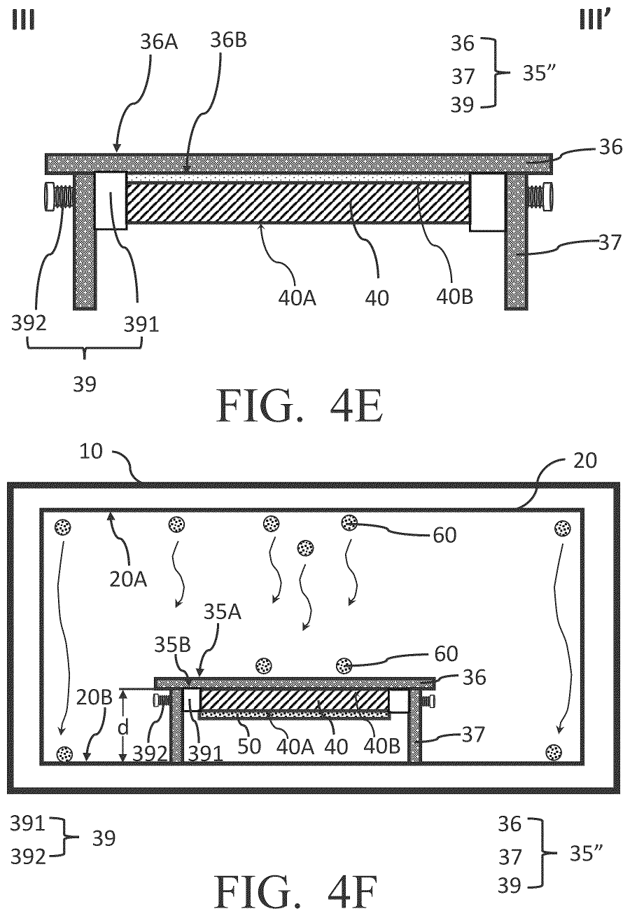

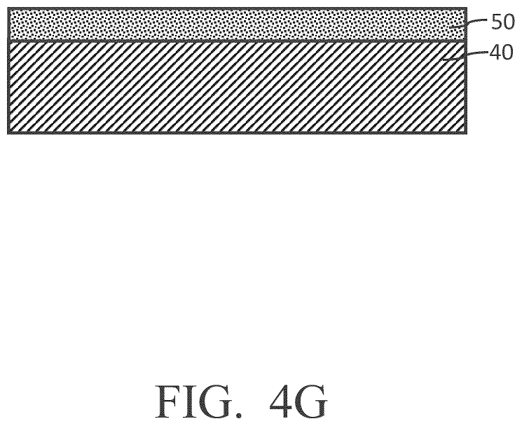

Please refer to FIG. 4A-4G, wherein 4A-4F are schematic drawings showing an atomic layer deposition (ALD) process according to Embodiment 3 of this present invention, FIG. 4G is a cross-sectional view of a sample with an atomic layer deposition (ALD) film formed thereon by the atomic layer deposition (ALD) process as shown in FIGS. 4A-4F.

First, an atomic layer deposition (ALD) apparatus 10 comprising a chamber 20 with a top part 20A and a bottom part 20B opposite to each other as shown in FIG. 4F was provided.

Next, a sample carrier 35″ comprising a stage 36, a plurality of supporting elements 37 and a plurality of side-clipped tenons 39 as shown in FIGS. 4A-4B was provided. The stage 36 comprises a top surface 36A and a bottom surface 36B opposite to each other, and the supporting elements 37 are disposed on the bottom surface of the stage 36, wherein each of the side-clipped tenons 39 comprises a tenon pad 391 and a screw 392, and each of the side-clipped tenons 39 is equipped with each of the supporting elements 37. As shown in FIGS. 4A-4B, each of the supporting elements 37 is sandwiched by a tenon pad 391 and a screw 392, and the screw 392 passes through the supporting element 37 to make the tenon pad 391 be laterally moved forward. The sample carrier 35″ can be made of a material selected from the group consisting of metal, ceramic and polymer or combinations thereof, for example but not limited to stainless, copper aluminum, aluminum oxide, Teflon or aluminum oxide coated aluminum product.

Next, a sample 40 with a coating surface 40A and a non-coating surface 40B opposite to each other as shown in FIGS. 4C-4E was provided, and the sample 40 was disposed and fasten on the bottom surface 36B of the stage 36 by the screw 392 passing through the supporting element 37 to make the tenon pad 391 be laterally moved forward to against the side edge (not labeled) of the sample 40. Although the tenon 39 used in this embodiment 3 comprising a tenon pad 391 and a screw 392, but other types of tennons can also alternatively be used in other Embodiments according to this invention.

Next, the sample carrier 35″ shown in FIGS. 4C-4E was placed on the bottom part 20B of the chamber 20 shown in FIG. 4F. As shown in FIG. 4F, the top surface 36A of the stage 36 faces the top part 20A of the chamber 20, and the bottom surface 36B of the stage 36 faces the bottom part 20B of the chamber 20 and spaced with each other by a distance of d (d>0). As shown in FIG. 4F, the coating surface 40A of the sample faces toward the bottom part 20B of the chamber 20, and the non-coating surface 40B faces toward the top part 20A of the chamber 20.

Next, an atomic layer deposition (ALD) process as shown in FIG. 4F was applied to make a reactant gas for atomic layer deposition (ALD) flow from the top part 20A of the chamber 20 to the bottom part 20B of the chamber 20 and the coating surface 40A of the sample 40 to form an atomic layer deposition (ALD) film 50 thereon.

The atomic layer deposition (ALD) film 50 according to this Embodiment 3 is a tantalum oxynitride film with a thickness for example but not limited to 10 nm deposited at a temperature for example but not limited to room temperature. Alternatively, the atomic layer deposition (ALD) film 50 can be another metal oxide film for example but not limited to a titanium oxide (TiO₂) film, an aluminum oxide (Al₂O₃) film, a hafnium oxide (HfO₂) film, a platinum oxide (PtO₂) film, an indium tin oxide (ITO) film or an indium gallium zinc oxide (IGZO) film. Alternatively, the atomic layer deposition (ALD) film 50 can also alternatively be a metal nitride film for example but not limited to an aluminum nitride (AlN) film, a molybdenum nitride (MoN) film, a titanium nitride (TiN) film or a tantalum nitride (TaN) film. Alternatively, the atomic layer deposition (ALD) film 50 can also alternatively be a metal oxynitride film.

Finally, the sample carrier 35″ was removed out of the chamber 20, and then the sample 40 was taken down from the stage 36 of the sample carrier 35. Thereafter, a sample 40 with an atomic layer deposition (ALD) film 50 formed on the coating surface 40A thereof as shown in FIG. 4G was obtained.

The surface of the obtained atomic layer deposition (ALD) film 50 formed on the coating surface 40A of the sample 40 is extremely flat because no sticky particles 60 on the side-wall (not labeled) of the chamber 20 fell down to the coating surface 40A of the sample 40 facing the bottom part 20B of the chamber 20 caused by the gravity during the atomic layer deposition (ALD) process.

Although particular embodiments have been shown and described, it should be understood that the above discussion is not intended to limit the present invention to these embodiments. Persons skilled in the art will understand that various changes and modifications may be made without departing from the scope of the present invention as literally and equivalently covered by the following claims.

What is claimed is:

1. A defect-reducing coating method, comprising the steps of:
providing an atomic layer deposition (ALD) apparatus comprising a chamber with a top part and a bottom part opposite to each other;
providing a sample carrier comprising a stage and a plurality of supporting elements, wherein the stage comprises a top surface and a bottom surface opposite to each other, and the supporting elements are disposed on the bottom surface of the stage;
providing a sample with a coating surface and a non-coating surface opposite to each other, wherein the sample is disposed and fasten on the bottom surface of the stage by the non-coating surface of the sample to make the coating surface of the sample face the bottom part of the chamber;
placed the sample carrier on the bottom part of the chamber, wherein the top surface of the stage faces the top part of the chamber, and the bottom surface of the stage faces the bottom part of the chamber and spaced with each other by a distance of d (d>0);
applying an atomic layer deposition (ALD) process to make a reactant gas for atomic layer deposition (ALD) flow from the top part of the chamber to the bottom part of the chamber and the coating surface of the sample to form an atomic layer deposition (ALD) film thereon; and
removing the sample carrier out of the chamber and take down the sample from the sample carrier.

2. The defect-reducing coating method as claimed in claim 1, wherein the sample carrier is made of a material selected from the group consisting of metal, ceramic and polymer or combinations thereof.

3. The defect-reducing coating method as claimed in claim 1, wherein the sample carrier is made of stainless, copper aluminum, aluminum oxide, Teflon or aluminum oxide coated aluminum product.

4. The defect-reducing coating method as claimed in claim 1, wherein a glue is coated or a double-sided tape is stick on the bottom surface of the stage and/or on the non-coating surface of the sample to make the sample be disposed and fasten on the bottom surface of the stage by the glue and/or the double-sided tape.

5. The defect-reducing coating method as claimed in claim 4, wherein the glue is a hot-melt adhesive, an epoxy resin, a carbon glue or a silver glue.

6. The defect-reducing coating method as claimed in claim 4, wherein the double-sided tape is a copper double-sided tape, a carbon double-sided tape or a polymer double-sided tape.

7. The defect-reducing coating method as claimed in claim 1, further comprising a plurality of baffles, wherein each of the baffles is equipped with each of the supporting elements, and the sample is disposed and fasten on the bottom surface of the stage by the baffles.

8. The defect-reducing coating method as claimed in claim 1, further comprising a plurality of baffles, wherein the baffles are disposed on the bottom surface of the stage, and the sample is disposed and fasten on the bottom surface of the stage by the baffles.

9. The defect-reducing coating method as claimed in claim 1, further comprising a plurality of side-clipped tenons, wherein each of the side-clipped tenons is equipped with each of the supporting elements, and the sample is disposed and fasten on the bottom surface of the stage by the side-clipped tenons.

10. The defect-reducing coating method as claimed in claim 1, further comprising a plurality of side-clipped tenons, wherein the side-clipped tenons are disposed on the bottom surface of the stage, and the sample is disposed and fasten on the bottom surface of the stage by the side-clipped tenons.

11. The defect-reducing coating method as claimed in claim 9, wherein each of the side-clipped tenons comprises a tenon pad and a screw.

12. The defect-reducing coating method as claimed in claim 10, wherein each of the side-clipped tenons comprises a tenon pad and a screw.
